(19) United States
(12) Patent Application Publication
(10) Pub. No.: US 2002/0025629 A1
(43) Pub. Date: Feb. 28, 2002

(54) Method of fabricating a capacitor structure

(75) Inventors: Gerrit Lange, Munchen (DE); Till Schlosser, Munchen (DE)

Correspondence Address: LERNER & GREENBERG P A, P.O. Box 2480, Hollywood, FL, 33022-2480, US

(73) Assignee: Siemens Aktiengesellschaft

(21) Appl. No.: 09/941,910

(22) Filed: Aug. 29, 2001

Related U.S. Application Data
(62) Division of application No. 09/395,305, filed on Sep. 13, 1999.

(30) Foreign Application Priority Data
Sep. 17, 1998 (DE) 198 42 684.4

(51) Int. Cl. H01L 21/00; H01L 21/8242

(52) U.S. Cl. 438/253; 438/396

(57) ABSTRACT

A method of fabricating a capacitor structure includes the steps of providing a carrier, forming a supporting structure on a surface of the carrier by providing at least two laminations spaced apart from one another and being disposed essentially parallel to the surface of the carrier and by mechanically connecting the two laminations to the carrier through the use of a connecting element. The method further includes the steps of conformally applying a noble-metal-containing first electrode material to an exposed surface of the carrier and to an exposed surface of the supporting structure, forming a first electrode by structuring the noble-metal-containing first electrode material, conformally applying a capacitor dielectric formed of one of a ferroelectric material and a material with a high dielectric constant on the first electrode; and forming a second electrode on the capacitor dielectric.

### CROSS-REFERENCE TO RELATED APPLICATION

This is a division of U.S. application Ser. No. 09/395,305, filed Sep. 13, 1999.

### BACKGROUND OF THE INVENTION

### FIELD OF THE INVENTION

The invention relates to a method of fabricating a capacitor structure which is arranged on a supporting structure in an integrated circuit, in which capacitor a dielectric with a high dielectric constant or a ferroelectric is used as the capacitor dielectric.

Capacitors are required in a large number of integrated semiconductor circuits, for example in DRAM circuits or A/D converters. Here, a main objective is to increase the integration density, i.e. the highest possible capacitance, or capacitance which is adequate for the requirements, must be realized with the minimum need for space. This problem is encountered in particular in the case of DRAM circuits in which each memory cell has a storage capacitor and a selection transistor, the surface which is available for a memory cell being continuously reduced. At the same time, in order to store the charge reliably and to distinguish reliably between the information which is to be read out, a certain minimum capacitance of the storage capacitor must be maintained. This minimum capacitance is currently taken to be approximately 25 fF.

In order to reduce the space which a capacitor requires, it is possible to use, as capacitor dielectric, a paraelectric with a high level of permittivity (dielectric with a high dielectric constant). In memory arrays, such capacitors are preferably used as so-called “stacked” capacitors (the capacitor of the cell is arranged above the associated selection transistor). Memory cells which use paraelectric materials as the dielectric for their capacitors lose their charge, and thus their stored information, when the supply voltage is selected. In addition, because of the residual leakage current, these cells must be continuously newly written to (refresh time). On the other hand, the use of a ferroelectric material as capacitor dielectric makes it possible, owing to the different polarization directions of the ferroelectric, to build a non-volatile memory (FRAM) which does not lose its information when the supply voltage is selected and does not need to be continuously newly written to either. The residual leakage current of the cell does not influence the stored signal.

Different ferroelectrics and dielectrics with a high dielectric constant are known from the literature, for example barium strontium titanate (BST), strontium titanate (ST) or lead zirconium titanate (BZT), in addition there are ferroelectric and paraelectric polymers and so on.

Although these materials have the desired electrical properties, their significance is still limited in practice. An essential cause of this is that the known materials cannot readily be used in semiconductor arrays. The materials are fabricated by means of a sputter-on or deposition process which requires high temperatures in an oxygen-containing atmosphere. This results in the conductive materials (for example polysilicon, aluminum or tungsten) which are used as electrode material in semiconductor technology being unsuitable because they oxidize under these conditions. For this reason, at least the first electrode is usually fabricated from a noble-metal-containing material such as platinum or ruthenium. However, these new electrode materials are relatively unknown substances for semiconductor technology. They are difficult to apply and can be structured adequately only with a low layer thickness. In addition, they are permeable to oxygen, the result of which is that during the fabrication of the capacitor dielectric lower lying structures are oxidized and sufficient contact between the first electrode and the selection transistor cannot be ensured. For this reason, it is necessary to have underneath the capacitor dielectric a barrier which suppresses oxygen diffusion.

In German Patent No. DE 196 40 448 and International Publication No. WO 98/14992 there is a description of such a memory cell in which the barrier between the first electrode and the structure connecting to the selection transistor is produced over the whole surface by means of nitridation. German Published, Non-Prosecuted Patent Application No. 196 40 244 A1 and International Publication No. WO 98/15014 describe a capacitor with a capacitor dielectric which has a high dielectric constant or is ferroelectric and in which the first electrode is composed of an electrode core and a noble-metal-containing layer which is thin in comparison with it, and in which the electrode core is composed of the material of the connecting structure or the oxidation barrier. This has the advantage that only a thin noble-metal-containing layer has to be structured.

All these capacitors with a capacitor dielectric which has a high dielectric constant or is ferroelectric have in common the fact that an, in principle, planar arrangement of the first electrode is provided.

In U.S. Pat. No. 5,581,436, a thin platinum layer is applied, as a first electrode of a capacitor of the type in question, to the surface of an electrode core. If appropriate, the dielectric with a high dielectric constant can be fabricated as a freely standing structure before the first and second electrodes are formed, i.e. the electrodes are then formed on the side walls of the dielectric.

### SUMMARY OF THE INVENTION

The object of the present invention is to specify a simple fabrication method, which is compatible with customary fabrication processes, for a capacitor structure.

This object is achieved by a fabrication method having the features of the claims.

The invention is based on the use of a supporting structure for the noble-metal-containing first electrode of the capacitor which has a surface which is significantly increased in comparison with its projection onto the carrier surface. The supporting structure comprises at least two laminations which are spaced apart from one another, lie essentially parallel to the carrier surface and are connected to the carrier by means of a connecting element. The noble-metal-containing first electrode covers the surface of the laminations and the connecting element, with the result that the surface with effective capacitance is increased. The second electrode of the capacitor is separated from the first electrode by a dielectric with a high dielectric constant or a ferroelectric.

The supporting structure can be implemented in a large number of different embodiments. The connecting element preferably also connects the laminations to one another and may be arranged on one or more sides of the laminations or may also run through the laminations in the interior. The supporting structure can in principle take on any shape which is known as first electrode in so-called “fin stack capacitors”. Such fin stack capacitors are described, for example, in Published, European Patent Application Nos. EP 415 530 B1, EP 779 656 A2, EP 756 326 A1 and in German Patent Nos. DE 198 21 910 C1, DE 198 21 776 C1 and DE 198 21 777 C1. However, in the present invention, the electrode structures described in said publications serve merely as a supporting structure for the noble-metal-containing first electrode. For this reason, there is a relatively large selection for the material of the supporting structure, which can also be composed of an insulator, and the connecting element does not need to connect the laminations electrically, but rather merely mechanically to the carrier.

The carrier can contain a connection for the first electrode, the rest of the surface of the carrier being covered with an insulating layer. Then, the noble-metal-containing first electrode covers part of the surface of the carrier and covers this connection so that an electrical contact is ensured.

In particular platinum, but also ruthenium oxide and other noble-metal-containing materials which are known for use in a capacitor which has a high dielectric constant or is ferroelectric are suitable as material for the first electrode. The second electrode is preferably composed of the same material as the first but may also be formed from another suitable material, for example another metal or doped polysilicon.

The capacitor is preferably used in a DRAM cell. The carrier then contains the associated MOS selection transistor. An S/D region of the transistor is connected to the first electrode by means of the aforementioned connection. The connection preferably has a conductive oxygen barrier (for example titanium nitride) in its upper region and is otherwise composed of, for example, titanium, polysilicon, tungsten or the like.

In order to fabricate the capacitor, the supporting structure is firstly produced on the carrier. The electrode material, for example, platinum, iridium or ruthenium oxide, is deposited in a conformal fashion onto the supporting structure. The electrode material is structured using a photo technique to form a first electrode. Before the resist layer which is required for the photo technique is applied, an auxiliary layer may be applied to the carrier, in particular in order to compensate the differences in height between the carrier surface and the upper edge of the electrode structure, which can lead to problems when exposing the photoresist. In this case, this auxiliary layer and the electrode material are structured with the resist mask and the auxiliary layer is then removed selectively with respect to the electrode material. After the structuring of the first electrode, a dielectric with a high dielectric constant or a ferroelectric is applied in conformal fashion using a known method, and the corresponding electrode is then fabricated.

One advantage of the method according to the invention is that there is no need for highly anisotropic etching of the electrode material.

In order to fabricate the supporting structure, a series of layers, which has in each case alternately a layer made of a first material and a layer made of a second material is produced on a carrier which can contain an insulating layer with a connection embedded in it, it being possible to etch the second material selectively with respect to the first. The series of layers is structured as far as the carrier, with the result that a layered structure with edges is formed. The connecting element is produced on at least one edge, for which purpose in particular implementation at an oblique angle, conformal deposition with subsequent anisotropic etching to form a spacer or a selective epitaxy can be used on the exposed surfaces of the layered structure. In the last two methods, an opening is then etched into the layered structure in order to expose a surface of the layers and to remove the layers made of the second material with a selective etching.

The opening can be laid against the edge of the layered structure so that the layer which forms the connecting element, and possibly an edge region of the layered structure are removed here.

On the other hand, the opening can be produced in the interior of the layered structure. As a result, a particularly high degree of stability is ensured when the second material is etched out, since the connecting element is present on all the outer edges of the supporting structure. The layers made of the first material can therefore be very thin, for example 20-30 nm.

Between the carrier and the series of layers it is possible to apply an auxiliary layer which serves as etch stop. The lowest layer of the series of layers is then preferably a layer made of the first material. The etching to form the layered structure can then take place in two etching steps, as can the etching to produce the opening; the first etching step being selective with respect to the auxiliary layer. A contact hole or barrier which is possibly present in the carrier is particularly well protected by this method. This advantage is beneficial particularly when an opening is made in the interior of the supporting structure, since during the fabrication of the opening it is necessary to etch down either as far as the carrier or as far as the layer lying directly on the carrier (which is in any case not resistant to the etching process used, the contact hole being preferably arranged in this region of the carrier surface. Without an auxiliary layer there may be the risk of the barrier being etched into. In addition, the selection of the first and second material, the carrier surface and the barrier determines whether the use of an auxiliary layer is advantageous. If the first material is the same as that of the carrier surface, the auxiliary layer permits, in particular, a reliable etch stop during the formation of the layered structure. Silicon oxide (specifically TEOS) or nitride, for example, is suitable as the auxiliary layer.

In order to fabricate the supporting structure it is possible to use the methods described in the patent applications cited above. As already explained, there is, however, a relatively large degree of freedom in the selection of suitable materials, since the only important factor is that the supporting structure which is to be produced should have a suitable geometric shape. This means that there are relatively wide selection possibilities for the etching processes also. For the use as a supporting structure, the series of layers (lst/2nd material) may be composed, for example, of p⁺-polysilicon/p⁻-polysilicon, silicon/germanium, n polysilicon/polysilicon, silicon oxide/silicon nitride, silicon nitride/silicon oxide, silicon oxide/ (doped if appropriate) polysilicon and other combinations; the laminations are then formed from the first material. The connecting element is preferably also formed from the first material so as to avoid making the later selective etching of the second material more difficult. The supporting structure can be composed of the same (insulating) material as the carrier surface with the result that the selective removal of the layers made of the second material is particularly simple and/or there is a large degree of freedom of selection for the second material and the selective etching process. However, there is then no selectivity with respect to the carrier when etching to form the layered structure if use is not made of an auxiliary layer. Fabrication methods and etching methods for germanium-containing layers are described in German Patent No. DE 197 07 977 C1.

Other features which are considered as characteristic for the invention are set forth in the appended claims.

Although the invention is illustrated and described herein as embodied in method of fabricating a capacitor structure, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1 to 6 show a cross section through a substrate on which a first exemplary embodiment of the method is illustrated in the form of a DRAM memory cell; and

FIGS. 7 to 12 correspondingly show a second exemplary embodiment.

### DESCRIPTION OF THE PREFERRED EMBODIMENTS

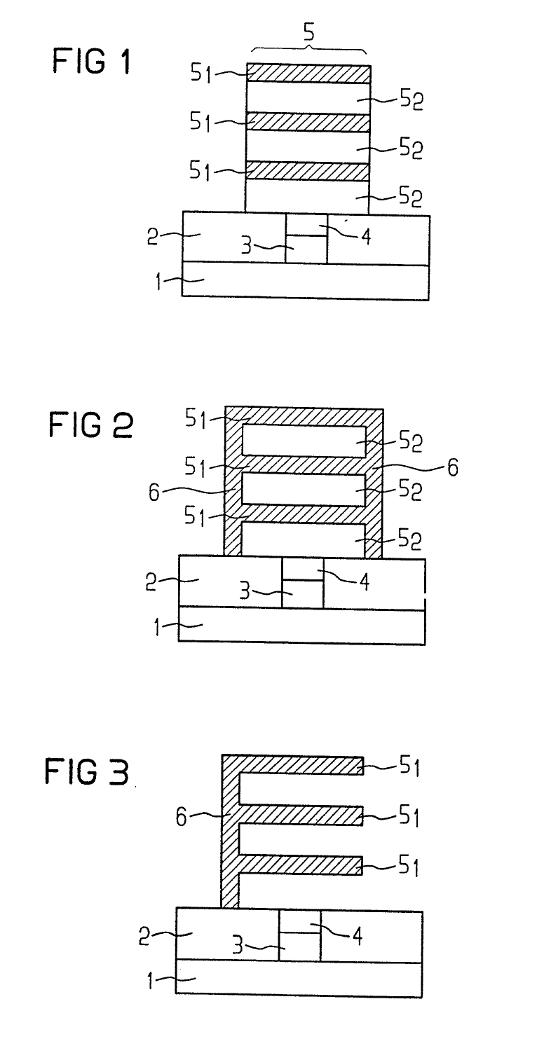

FIG. 1: An insulating layer 2 is applied to a substrate 1. The substrate 1 is, for example, a silicon substrate which comprises selection transistors with word lines and bit lines (see FIG. 6). The insulating layer is formed, for example, from silicon oxide and planarized. Contact holes 3 are made in the insulating layer 2 and filled with electrically conductive material, for example doped polysilicon, tungsten, tantalum, titanium, titanium nitride or tungsten silicide. The contact holes 3 are arranged in such a way that they each extend to a source/drain region of a selection transistor in the substrate 1. A barrier 4, which suppresses oxygen diffusion, is preferably arranged in the upper part of the contact hole 3. Methods for fabricating such a barrier are known, for example, from German Patent No. DE 196 40 448 C1 or German Published, Non-Prosecuted Patent Application No. DE 196 40 246 A1. The supporting structure is then fabricated on this carrier in that firstly a series of layers, which comprises alternately a layer 5₁ made of a first material and a layer 5₂ made of a second material, is applied. The first material is composed, for example, of silicon oxide and the second material of undoped or doped polysilicon. Furthermore, the first material can be composed of p⁺doped polysilicon and the second material of p⁻-doped polysilicon. Generally, the first material must form a suitable underlying layer for a noble-metal-containing layer, and the second material must be capable of being etched selectively with respect to the first material and with respect to the carrier surface (or with respect to a possible auxiliary layer) and possibly with respect to the barrier material. In this exemplary embodiment, the layer made of the second material is applied directly to the carrier surface. The top layer of the series of layers is composed of the first material in this exemplary embodiment. A layered structure 5 is then formed from the series 5 of layers by anisotropic etching using a mask. Next to the layered structure, the surface of the insulating layer 2 is exposed.

FIG. 2: Spacers 6, preferably made of the first material, are formed on the side walls of the layered structure 5 by depositing in conformal fashion a layer made of the first material and etching it back anisotropically.

FIG. 3: An opening which exposes the edges of the layers made of the first and the second materials is then etched into this structure. In this exemplary embodiment, this opening is positioned on the side of the structure, i.e. the spacer which is located on one side and an adjoining edge region of the layered structure 5 are removed with a suitable etching process using a photo mask. However, the opening can also be positioned at another location, the only significant factor is that at least one surface or edge of each of the layers made of the second material should be exposed. In the patent applications cited above, other examples of ways of producing the invention are disclosed. The remaining spacer 6 constitutes the connecting element. The layers 5₂ made of the second material are removed with an etching process with an isotropic component, which process does not attack the layers made of the first material, the connecting element 6, the carrier surface 2 or the barrier 4. Suitable etching processes are known to the person skilled in the art and are described, for example, in the patent applications cited. In this way, a supporting structure is formed which is composed of laminations 5₁ which are spaced apart from one another and of the connecting element 6. The connecting element 6 mechanically connects the laminations 5₁ to one another and to the carrier surface.

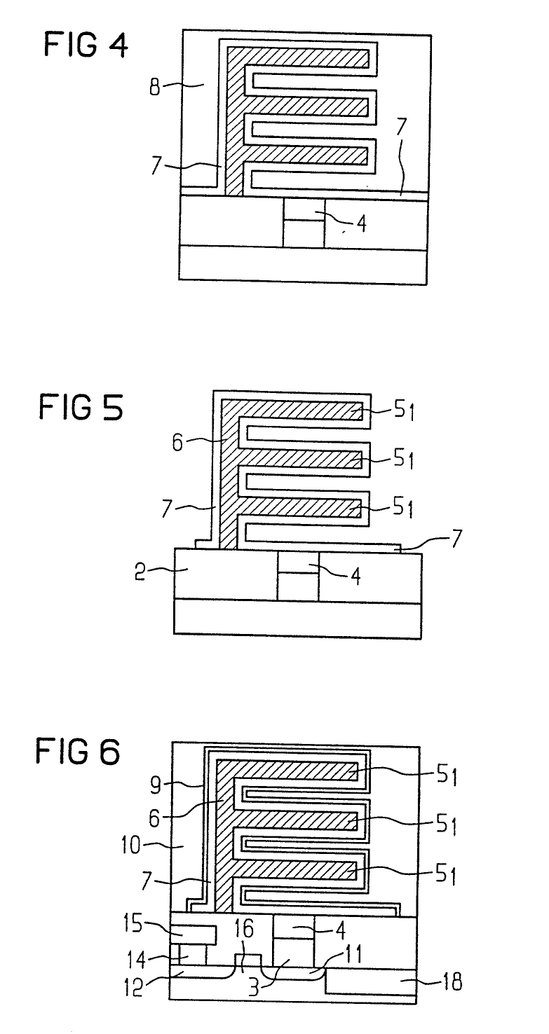

FIG. 4: Platinum 7 is deposited in conformal fashion as noble-metal-containing electrode material onto the supporting structure 5₁, 6. Methods which are suitable for this (in particular MOCVD) are known from the U.S. patent disclosed above. An auxiliary layer 8 is then applied in conformal fashion so that the structure which is present is thus filled and the surface is partially leveled off. The auxiliary layer must be capable of being etched selectively with respect to the material of the first electrode and can be composed, for example, of TEOS or nitride.

FIG. 5: A suitable resist mask (not illustrated) is applied and the auxiliary layer and the electrode layer 7 are etched anisotropically. The electrode layer 7 is etched here in accordance with the dimensions of the first electrode. The auxiliary layer 8 is then removed, for example, with a wet method selectively with respect to the electrode material. The first electrode 7 also covers part of the carrier surface, and in particular the connection 3, 4. This ensures electrical contact between the connection and the first electrode.

FIG. 6: The capacitor dielectric composed of a dielectric with a high dielectric constant or a ferroelectric 9 is applied with a known method. The high temperature process which is used here does not cause the lower lying structures to oxidize since oxygen diffusion is prevented by the barrier 4. Finally, a conductive layer is applied to form the corresponding electrode 10.

This FIG. 6 also shows further structures which are implemented in the carrier and which are present when the capacitor is used in a DRAM circuit. The first electrode 7, which is arranged on the supporting structure 5₁, 6, forms the so-called storage node for a storage capacitor. This first electrode is connected to a source/drain region 11 of a selection transistor via the contact 3 which is arranged under said first electrode and is provided with the diffusion barrier 4. The other source/drain region 12 of the selection transistor is connected to a buried bit line 15 via a bit line contact 14. Two adjacent memory cells preferably have a common bit line contact. The buried bit line 15 and the bit line contact 14 are surrounded by the insulating layer 2. The channel region 16, a gate dielectric (not illustrated) and a gate electrode which acts as a word line 17 are arranged between the source/drain regions 11 and 12 of a selection transistor. The word line 17 and the bit line contact 14 are each formed from doped polysilicon. The bit line 15 is formed from doped polysilicon, tungsten silicide or tungsten. An insulating structure, for example a flat trench 18, filled with insulating material for providing insulation between adjacent pairs of selection transistors is provided in each case on the side of the S/D region 11 facing away from the bit line 15.

In a further embodiment, the supporting structure, i.e. the laminations 5₁ and the connecting element 6, is composed of p-type doped polysilicon. The series of layers (see FIG. 1) can then preferably be composed of p⁻-doped silicon 5₂ and p⁺-doped silicon 5₁. The lowest layer here is a p⁻-doped polysilicon layer 5₂. The connecting element (see FIG. 2) can be fabricated as a spacer, as in the first exemplary embodiment, but it can also be produced by selective epitaxy, as described in Published, European Patent Application No. EP 779 656 A2. The top layer of the series of layers in FIG. 1 is then preferably a p⁻-doped polysilicon layer 5₂. A further possibility is to produce the connecting element by implantation at an oblique angle into a side wall of the layered structure 5 in FIG. 1. This edge region is then highly doped, while the doping of the edge region lying opposite is not changed. Such a method is described in Published, European Patent Application No. EP 756 326 A1. In this case, there is no need to etch a further opening into the layered structure 5, since the edges of the layers made of the second material are exposed at the edge lying opposite. After the connecting element 6 is produced, the layers made of the second material 5₂, that is to say the p⁻-doped silicon layers, are removed selectively with respect to the p+ doped polysilicon 5₁, 6, with respect to the carrier and with respect to the barrier. Suitable etching methods are known to the person skilled in the art and are described, for example, in the patent application cited above. The supporting structure is thus completed and the rest of the method can be executed as in the first exemplary embodiment. During the high temperature process for producing the capacitor dielectric, oxidation of the supporting structure 5₁, 6 has to be expected. However, this is undamaging because the electrical contact between the first electrode and the connecting structure 3, 4 takes place directly (see FIG. 6), and the electrical conductivity of the supporting structure is insignificant.

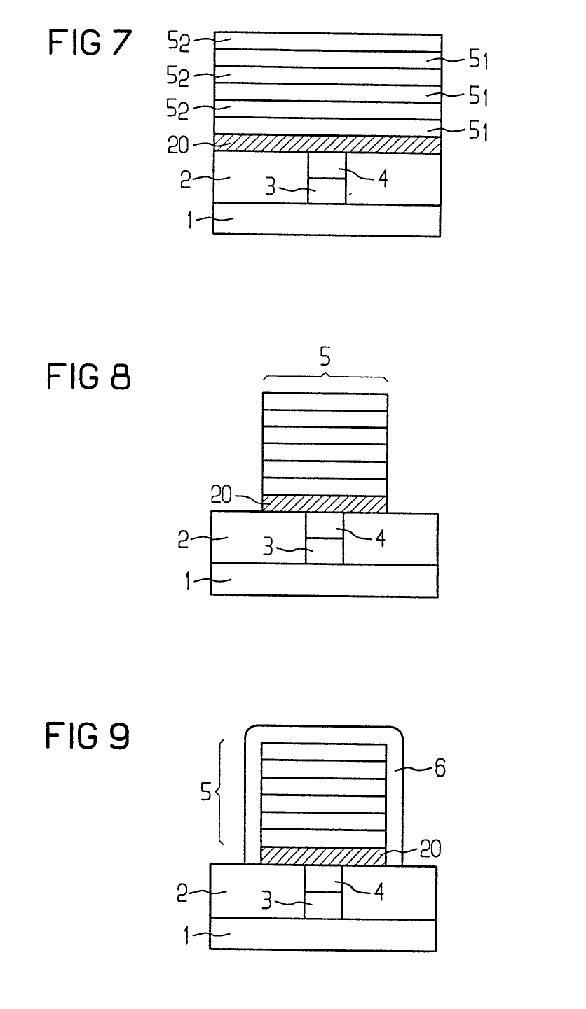

A further exemplary embodiment is illustrated in FIGS. 7 to 12.

FIG. 7: An insulating layer 2 is applied to a substrate 1. The substrate 1 is, for example, a silicon substrate which comprises selection transistors with word lines and bit lines (see FIG. 6). The insulating layer is formed, for example, from silicon oxide and planarized. Contact holes 3 are made in the insulating layer 2 and filled with electrically conductive material, for example with doped polysilicon, tungsten, tantalum, titanium, titanium nitride or tungsten oilicide. The contact holes 3 are arranged in such a way that they extend in each case to a source/drain region of a selection transistor in the substrate 1. A barrier 4, which suppresses oxygen diffusion, is preferably arranged in the upper part of the contact hole 3. Methods for fabricating such a barrier are known, for example, from German Published, Non-Prosecuted Patent Application Nos. DE 196 40 246 and DE 196 40 448. The supporting structure is then fabricated on this carrier by firstly applying an etch stop layer 20 and a series of layers on top of it, said series of layers comprising alternately a layer 5₁ made of a first material and a layer 5₂ made of a second material. In this example, the first material is composed of p⁺-doped polysilicon, the second material of p⁻-doped polysilicon and the etch stop layer of TEOS or nitride. The lowest layer of the series of layers is composed of the first material and the top layer of the series of layers is composed of the second material.

FIG. 8: A layered structure 5 is then formed from the series of layers by means of anisotropic etching using a mask, in the process the etch stop layer 20 is also etched if appropriate in a second etching step. Next to the layered structure the surface of the insulating layer 2 is exposed. The anisotropic etching can be carried out with CF₄ and SF₆.

FIG. 9: The layered structure 5 made of p⁺doped polysilicon and p⁻-doped polysilicon has silicon grown over it by means of selective epitaxy, with the result that the connecting element 6 which covers the layered structure completely is formed. The epitaxy can be executed in the temperature region between 700° C. and 750° C. with the process gases SiC₁₂H₂, HC₁, and H₂ as well as a dopant gas such as B₂H₆, with the result that the layers are prevented from diffusing into one another. With a series of layers made of silicon and germanium-containing layers the temperature may be up to 900° C.

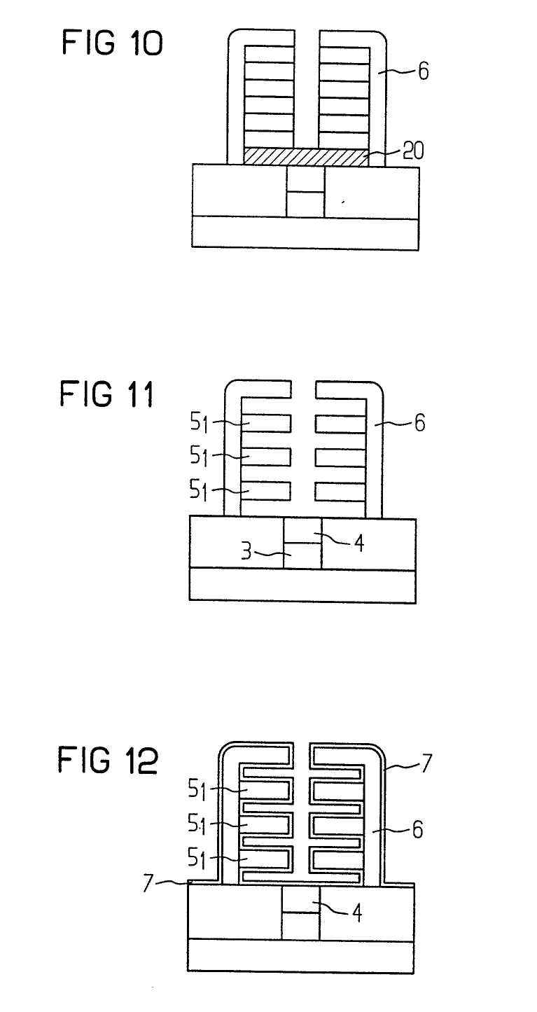

FIG. 10: An opening, which exposes the edges of the layers made of the first and second materials, is then etched into this structure using a photo mask. In this exemplary embodiment, this opening is made into the interior of the structure. In a first anisotropic etching step, the series of layers is etched with HBr and chlorine, for example, and in a second etching step with an isotropic component the etch stop layer which covers the connection 3, 4 is selectively removed.

FIG. 11: The layers 5₂ made of the second material are removed with an etching process with an isotropic component, which does not attack the layers made of the first material or the connecting element 6 (if appropriate before or at the same time as the removal of the etch stop layer). For this purpose, an alkaline etching solution can be used which contains ethylenediamine, brengkatechin, pyrazine and water. The selectivity (etching rate P⁺-Si/P⁻-Si) is approximately 1:500. In this way a supporting structure is formed which is composed of laminations 5₁ which are spaced apart from one another and of the connecting element 6. The connecting element 6 mechanically connects the laminations 5₁ to one another and to the carrier surface at all the outer sides of the supporting structure.

FIG. 12: Platinum is deposited in conformal fashion as noble-metal-containing electrode material onto the supporting structure 5₁, 6. The connection 3, 4 is exposed in the vicinity of the opening in the interior of the supporting structure with the result that the contact with the electrode layer 7 is ensured here. Suitable methods for conformal deposition of platinum are known from the US patent disclosed above. The method is then continued as in the first exemplary embodiment, that is to say, if appropriate, the auxiliary layer 8 is applied in conformal fashion (see FIG. 4 et seq.) and the first electrode is structured etc.

We claim:

1. A method of fabricating a capacitor structure, the method which comprises:
providing a carrier;
forming a supporting structure on a surface of the carrier by providing at least two laminations spaced apart from one another and being disposed essentially parallel to the surface of the carrier and by mechanically connecting the at least two laminations to the carrier through the use of a connecting element;
conformally applying a noble-metal-containing first electrode material to an exposed surface of the carrier and to an exposed surface of the supporting structure;
forming a first electrode by structuring the noble-metal-containing first electrode material;
conformally applying a capacitor dielectric formed of one of a ferroelectric material and a material with a high dielectric constant on the first electrode; and
forming a second electrode on the capacitor dielectric.

2. The method according to claim 1, wherein the step of forming the supporting structure includes:
applying an alternating series of layers of a first material and layers of a second material on the carrier;
etching the alternating series of layers for forming a layered structure with edges;
forming the connecting element such that the connecting element covers at least one of the edges of the layered structure; and
selectively removing the layers formed of the second material with respect to the layers formed of the first material and with respect to the connecting element for forming the supporting structure.

3. The method according to claim 2, which comprises:
forming the layers made of the first material from p⁺-doped polysilicon; and
forming the layers made of the second material from p⁻-doped polysilicon.

4. The method according to claim 2, which comprises forming the layers made of the first material from an insulating material.

5. The method according to claim 3, which comprises forming the connecting element by an oblique implantation into one of the edges of the layered structure.

6. The method according to claim 2, which comprises:
forming the connecting element by one of a selective epitaxy and a conformal deposition on all edges of the layered structure, and by a subsequent anisotropic etching; and
etching an opening into the layered structure for exposing a surface of the layers made of the first material.

7. The method according to claim 2, which comprises:
conformally applying an auxiliary layer after the step of applying the first electrode material;
anisotropically etching the auxiliary layer and the first electrode material for forming the first electrode; and
removing a remaining part of the auxiliary layer selectively with respect to the first electrode.

8. The method according to claim 1, which comprises applying an etch stop layer on the surface of the carrier, prior to the step of forming the supporting structure.
